(19) United States
(12) Patent Application Publication
(10) Pub. No.: US 2025/0244361 A1
(43) Pub. Date: Jul. 31, 2025

(54) TEST SOCKET FOR OPTICAL FAULT ISOLATION AND OPTICAL FAULT ISOLATION APPARATUS INCLUDING THE SAME

(71) Applicant: Samsung Electronics Co., Ltd., Suwon-si (KR)

(72) Inventors: WOOK-JIN LEE, Suwon-si (KR); DAIYUN KIM, Suwon-si (KR); GHIL-GEUN OH, Suwon-si (KR)

(21) Appl. No.: 18/964,973

(22) Filed: Dec. 2, 2024

(30) Foreign Application Priority Data
Jan. 26, 2024 (KR) 10-2024-0012540

(51) Int. Cl. G01R 1/04; G01R 31/28; G01R 31/311

(52) U.S. Cl. CPC G01R 1/0441; G01R 31/2891; G01R 31/311

(57) ABSTRACT

A test socket according to an embodiment includes a socket base configured to support a device under test; a socket cover including a cover part covering the socket base, and the cover part includes a through opening configured to house the device under test; and a heating unit on the socket cover, wherein the heating unit includes a graphene structure covering the through opening; and a first transparent plate on the graphene structure, wherein the graphene structure includes a first region positioned on the through opening; and a second region around the first region, the first region and the second region are non-overlapping portions of a major plane of the graphene structure, the graphene structure has a first thickness in a vertical direction in the first region and a second thickness in the vertical direction in the second region, and the first thickness is thinner than the second thickness.

### CROSS-REFERENCE TO RELATED APPLICATION

This application claims priority to and the benefit of Korean Patent Application No. 10-2024-0012540 filed in the Korean Intellectual Property Office on Jan. 26, 2024, the entire contents of which are incorporated herein by reference.

### BACKGROUND OF THE INVENTION

### (a) Field of the Invention

The present disclosure relates to a test socket for an optical fault isolation and an optical fault isolation apparatus including the same.

### (b) Description of the Related Art

Semiconductor fault analysis is performed on semiconductor products to find causes of faults in the semiconductor products and improve them. As the process for manufacturing the semiconductor products becomes more refined and the size of a unit logic within semiconductor products becomes smaller, it has become difficult to physically visualize actual faults in the semiconductor products, to solve these problems, optical fault isolation (OFI) devices, which use an optical technology to visualize the actual faults within the semiconductor products, are being utilized. The optical fault isolation (OFI) device is connected to an automatic test equipment (ATE) that actually operates a semiconductor chip and the fault positions inside the semiconductor chip are detected by radiating light to the back side of the semiconductor chip while the actual semiconductor chip is operating by using the automatic test equipment (ATE).

Meanwhile, since the semiconductor chips (e.g., semiconductor chips for automobiles) that operate in a high temperature environment must have their quality guaranteed at a high temperature of 105° C. or higher and must not be deteriorated in a temperature change between a room temperature and the high temperature, a high temperature fault test must be essentially performed. High temperature faults that may occur in these semiconductor chips are mainly temperature margin faults and even if the semiconductor chip is judged to be faulty, often it will operate normally again if the temperature is lowered, so that the fault position within the semiconductor chip must be found by performing the test of the semiconductor chip in a high temperature environment.

However, since conventional optical fault isolation (OFI) devices are designed to enable analysis at room temperature and have a structure exposed to room temperature, analysis at high temperatures is not possible. In addition, since the conventional optical fault isolation (OFI) device must be connected to the automatic test equipment (ATE) to operate the semiconductor chip, and the size of the optical fault isolation (OFI) device is large, it is also difficult to place the optical fault isolation (OFI) device within a temperature control chamber.

Therefore, there is a need to develop a new optical fault isolation (OFI) technology that may perform fault testing of the semiconductor chips in a high temperature environment.

### SUMMARY OF THE INVENTION

In a test socket including a socket base that fixes a test target device (Device Under Test; DUT) and a socket cover on the socket base, a heating unit made of a graphene structure with excellent electrical conductivity, thermal conductivity, and optical transmittance may be placed on the socket cover.

In a test socket that includes a socket base that fixes the device under test (DUT) and a socket cover on the socket base, at least one of a heating part or an insulating part may be provided in the socket cover.

A test socket including a socket base that fixes the device under test (DUT), a socket cover on the socket base, and a heating unit made of a graphene structure may be provided to an optical fault isolation (OFI) device.

A test socket according to an embodiment includes a socket base configured to support a device under test (DUT); a socket cover on the socket base, wherein the socket cover includes a cover part of covering the socket base, and the cover part includes a through opening configured to house the device under test (DUT); and a heating unit on the socket cover, wherein the heating unit includes a graphene structure covering the through opening, and a first transparent plate on the graphene structure, wherein the graphene structure includes a first region positioned on the through opening; and a second region around the first region, the first region and the second region are non-overlapping portions of a major plane of the graphene structure, the graphene structure has a first thickness in a vertical direction in the first region and a second thickness in the vertical direction in the second region, and the first thickness is thinner than the second thickness.

A test socket according to an embodiment includes a socket base configured to support a device under test (DUT); a socket cover on the socket base, wherein the socket cover includes a cover part that covers the socket base and includes a through opening sized and shaped to receive the device under test (DUT); and a first graphene structure around the through opening; and a heating unit on the socket cover, wherein the heating unit includes a second graphene structure covering the through opening; and a transparent plate on the second graphene structure, wherein the second graphene structure includes a first region positioned on the through opening, and a second region around the first region, and the first region and the second region are non-overlapping portions of a major plane of the graphene structure, the graphene structure has a first thickness in a vertical direction in the first region and a second thickness in the vertical direction in the second region, and the first thickness is thinner than the second thickness.

An optical fault isolation apparatus according to an embodiment includes a test socket, wherein the test socket includes a socket base configured to support a device under test (DUT); a socket cover on the socket base, wherein the socket cover includes a cover part of covering the socket base, and the cover part includes a through opening sized and shaped to receive the device under test (DUT); and a heating unit on the socket cover, wherein the heating unit includes a graphene structure covering the through opening, the graphene structure includes a first region positioned on the through opening; and a second region around the first region, the first region and the second region are non-overlapping portions of a major plane of the graphene structure, the graphene structure has a first thickness in a vertical direction in the first region and a second thickness in the vertical direction in the second region, and the first thickness is thinner than the second thickness, an optical device including a laser light source; and a housing that accommodates the optical device, wherein the housing has an opening on an upper surface of the housing, and the test socket is mounted in the opening.

The heating unit is manufactured using the graphene structure which has excellent electrical conductivity, thermal conductivity, and optical transmittance, and such a heating unit may be placed in the test socket to perform the optical fault isolation (OFI) of the device under test (DUT) in a high temperature environment.

By placing the socket cover including at least one of the heating part or the insulating part on the test socket, the optical fault isolation (OFI) of the device under test (DUT) may be performed in a high temperature environment, and heat generated through the heating unit may be minimized from being lost to the outside through the test socket.

Using the optical device, faults occurring within the device under test (DUT) in a high temperature environment may be actually visualized and causes of the fault may be found. As a result, the quality of semiconductor products operating in a high temperature environment may be improved and the yield may be improved.

### BRIEF DESCRIPTION OF THE DRAWINGS

FIG. 1 is a schematic view of an optical fault isolation system including an optical fault isolation apparatus of an embodiment.

FIG. 2 is a view showing a cross-section of a test socket of an embodiment.

FIG. 3 is a view showing another cross-section of the test socket of an embodiment.

FIG. 4 is a top plan view showing a test socket of an embodiment including a heating unit.

FIG. 5 is a top plan view showing a test socket of an embodiment without a heating unit.

FIG. 6 is a cross-sectional view showing a heating unit of an embodiment.

FIG. 7 is a graph showing the transmittance of a graphene layer according to a wavelength of a light source.

FIG. 8 is a graph showing an internal temperature and an analysis image quality of a socket according to a number of graphene layers.

FIG. 9 is a cross-sectional view showing a heating unit of an embodiment.

FIG. 10 is a cross-sectional view showing a heating unit of an embodiment.

FIG. 11 is a cross-sectional view showing a socket cover of an embodiment.

FIG. 12 is a top plan view showing a test socket of an embodiment without a heating unit.

FIG. 13 is a cross-sectional view showing a socket cover of an embodiment.

FIG. 14 is a top plan view showing a test socket of an embodiment without a heating unit.

FIG. 15 is a cross-sectional view showing a socket cover of an embodiment.

FIG. 16 is a top plan view showing a test socket of an embodiment without a heating unit.

FIG. 17 is a cross-sectional view showing a socket cover of an embodiment.

FIG. 18 is a top plan view showing a test socket of an embodiment without a heating unit.

FIG. 19 is a cross-sectional view showing a socket cover of an embodiment.

### DETAILED DESCRIPTION OF THE EMBODIMENTS

Hereinafter, with reference to the accompanying drawings, the present disclosure will be described in detail such that those skilled in the art may easily carry out aspects of the present disclosure. However, the inventive concept may be embodied in many different forms and is not limited to the embodiments set forth herein.

In addition, to clearly describe the present disclosure, a description of parts unrelated to the inventive concept may be omitted, and the same or similar elements are denoted with the same reference numerals throughout the specification.

The size and thickness of the configurations are optionally shown in the drawings for convenience of description, and the inventive concept is not limited to the configurations shown in the drawings.

Throughout the present specification, when a part is referred to as being “connected to” another part, it means that the part and another part may be “directly connected to” each other or are “indirectly connected to” each other. When parts are “directly connected” the parts contact each other with no other intervening parts. When parts are “indirectly connected” there are intervening parts interposed between the parts that are “indirectly connected” such that the parts do not contact one another.

As used herein, components described as being “electrically connected” are configured such that an electrical signal can be transferred from one component to the other (although such electrical signal may be attenuated in strength as it is transferred and may be selectively transferred).

It will be understood that, although the terms first, second, third etc. may be used herein to describe various components and/or regions, these components and/or regions should not be limited by these terms. Unless the context indicates otherwise, these terms are only used to distinguish one component, plurality of components component, region, or plurality of regions from another component or region, for example as a naming convention. Thus, a first component or could be termed a second component or region in different sections of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other. Additionally, it will be understood that the use of first, second, third etc. may refer to a plurality of components having a common function, feature, structure, and/or description even when not expressly described as a plurality.

In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element, or intervening elements may also be present. In contrast, when an element is referred to as being “directly on” another element, there are no intervening elements present. Further, in the specification, the word “on” means positioned above or below the object portion. “Above” and “below” are used in reference to the orientation shown in the drawings and may not be applicable in other orientations. Additionally, “above” and “below” are not based on a gravitational direction.

Further, in the specification, the phrase “in a plan view” means when an object portion is viewed from above (e.g., as viewed from a viewpoint above a horizontal plane, which may be defined by a substrate), and the phrase “in a cross-sectional view” means a side view of a cross-section taken by vertically cutting an object portion and looking at the cut object portion.

Hereinafter, an optical fault isolation system 10, an optical fault isolation apparatus 200, and a test socket 100 according to embodiments will be described with reference to accompanying drawings.

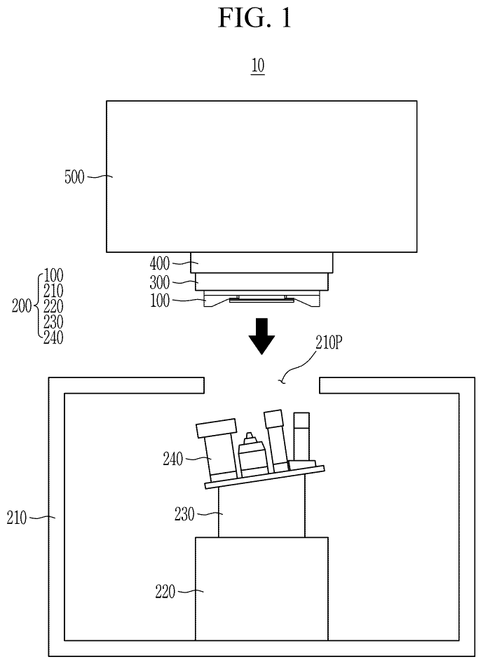

FIG. 1 is a schematic view of an optical fault isolation system 10 including an optical fault isolation apparatus 200 of an embodiment.

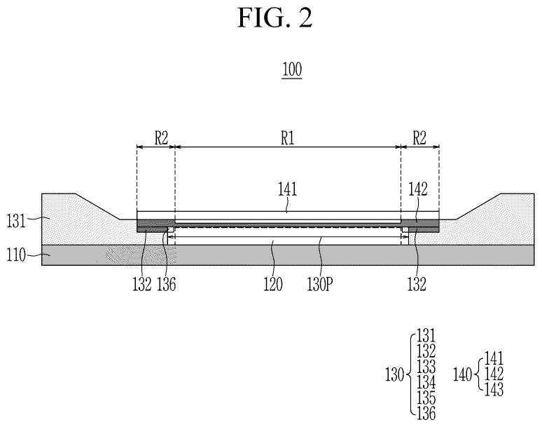

Referring to FIG. 1, an optical fault isolation system 10 includes an optical fault isolation apparatus 200, a probe card 300, an interface module 400, and automatic test equipment (ATE; 500). The optical fault isolation system 10 has a structure in which the optical fault isolation apparatus 200 equipped with a device under test (DUT; 120; referring to FIG. 2) and the automatic test equipment 500 that operates the device under test 120 are linked. In the optical fault isolation system 10, the automatic test equipment 500 operates the device under test 120, and the optical fault isolation apparatus 200 irradiates the back surface of the device under test 120 with a laser light, which may be referred to as a “laser” of “light” for short, while the device under test 120 is operating to obtain an image of the inside of the device under test 120 and detect the fault position inside the device under test 120.

The optical fault isolation apparatus 200 includes a test socket 100, a housing 210, an optical device 220, an optical turret 230, and lenses 240.

The test socket 100 is configured to be mounted to the housing 210 and at least a portion of the test socket 100 may extend into the housing 210. Referring to FIG. 1 and FIG. 2, the test socket 100 is configured to be mounted at an opening 210P of the housing 210 so that a socket cover 130 faces the lenses 240 and a socket base 110 faces the probe card 300. The socket base 110 is configured to be selectively attached and detached to/from the probe card 300 and is electrically connected to the probe card 300 to be turned on/off. The test socket 100 is electrically connected to the automatic test equipment (ATE; 500) and may be connected through the probe card 300 and the interface module 400 to the automatic test equipment 500. In an embodiment, the test socket 100 may be configured to have various structures and shapes depending on the shape and type of the device under test 120 (referring to 2). The structure and shape of the test socket 100 may be sized and shaped to support and/or receive a device under test 120. For example, the test socket 100 may have a recess that conforms to a particular device under test 120. In an embodiment, the test socket 100 may have a structure and a shape corresponding to a ball grid array (BGA), a plastic leaded chip carrier (PLCC), a plastic dual in-line package (PDIP), a ceramic dual in-line package (CERDIP), a plastic metric quad flat pack (MQFP), a thin quad flatpack (TQFP), a small outline (SOIC), a shrink small outline package (SSOP), a thin small outline (TSOP), or a thin quad flatpack (TQFP).

The housing 210 provides a space where the test socket 100 may be mounted, such as at the opening 210p, and a space where the optical device 220, the optical turret 230, and the lenses 240 are accommodated, such as an internal space of the housing 210. The housing 210 includes an opening 210P on the upper surface thereof. The test socket 100 may be mounted in or at the opening 210P. The housing 210 includes a fixing unit configured to mount and fix the test socket 100 to the opening 210P. For example, a fixing unit may be a bracket or collar that may be secured to the housing to hold the test socket 100 in place. In an embodiment, the opening 210P may have various shapes depending on the shape and type of the test socket 100.

The optical device 220 is disposed inside the housing 210. The optical device 220 irradiates a device under test 120 mounted within the test socket 100 with a laser, obtains an image of the device under test 120 from the reflected laser, and detects a fault position inside the device under test 120 from the image. The optical device 220 moves within the housing 210 by way of a transfer device to irradiate different portions of the device under test. In an embodiment, the optical device 220 may include a laser light source for producing the laser light and which irradiates the device under test 120 with the laser and a detection part, such as an optical sensor, which detects a reflection of the laser from the device under test 120. The optical device 220 may include liquefied nitrogen therein. The liquefied nitrogen may maintain an extremely low temperature of the optical device 220 of about 87K, and thus, internal images of the device under test 120 may be obtained with high quality and high magnification.

The optical turret 230 is placed on the optical device 220 and configured to be rotated. For example, a motor may be controlled to selectively rotate the optical turret to a set position. The lenses 240 are disposed on the optical turret 230 and each of the lenses 240 includes various magnifications and functions. The optical turret 230 is configured to be rotated, such as by a motor, and through the rotation of the optical turret 230, an optical lens 240 having the desired magnification and function among the optical lenses 240 may be selected to use in an optical fault isolation test.

The optical fault isolation apparatus 200 may be used to perform an internal optical fault isolation (OFI) of the device under test 120. In an embodiment, the optical fault isolation (OFI) may implement inspection techniques including photon emission microscopy (PEM), dynamic laser stimulation (DLS), and/or laser voltage probing (LVP).

The photon emission microscopy (PEM) is a method that detects and analyzes photons emitted from the device under test 120 with an optical device 220 during the operation of the device under test 120 (e.g., when a voltage is applied to the transistor and a current flows). If a fault occurs in an internal circuit of the device under test 120, a current leakage and a floating node occur, which creates a section where a current that deviates from a reference value flows. The optical fault isolation apparatus 200 detects the fault position inside the device under test 120 by capturing near-infrared radiation of the current that deviates from the reference value.

The dynamic laser stimulation (DLS) is a method to verify whether a circuit is operating normally or abnormally by irradiating the operating device under test 120 with a laser in a near-infrared region to impart local changes (e.g., changes in voltage and current characteristics, or temperature changes). The optical fault isolation apparatus 200 detects the fault position inside the device under test 120 by irradiating a local area of the device under test 120 in operation with a laser in the near-infrared region.

The laser voltage probing (LVP) is a method to verify whether a circuit is operating normally or abnormally by irradiating the device under test 120 in operation with a laser and converting the reflectance of the laser reflected from the device under test 120 into a signal form to monitor the waveform of the internal circuit of the device under test 120. The optical fault isolation apparatus 200 irradiates the device under test 120 with a laser, detects the laser reflected from the device under test 120, and detects the fault position inside the device under test 120.

The probe card 300 may be selectively attached and detached to the test socket 100. The probe card 300 may be electrically and physically connected to the test socket 100. The probe card 300 may be connected to the test socket 100 through electrical terminals. In an embodiment, the electrical terminals may include solder balls, bumps, or pins. Probes of the probe card 300 may be electrically connected to terminals formed on traces on the front side of the device under test 120 through the test socket 100.

The interface module 400 may be selectively attached and detached to/from the probe card 300. The interface module 400 may be electrically and physically connected to the probe card 300. The interface module 400 transmits electrical signals between the probe card 300 and the automatic test equipment (ATE; 500). The interface module 400 includes a pogo block. The pogo block includes pogo pins. The pogo pins are in contact with a conductive pattern formed on the circuit board of the probe card 300 and are electrically connected to the probe card 300.

The automatic test equipment (ATE; 500) is electrically and physically connected to the interface module. The automatic test equipment (ATE; 500) generates an input signal to be applied to the device under test 120 in response to instructions in a test program, provides the generated input signal to the device under test 120, and monitors the output signal device under test 120. The automatic test equipment (ATE; 500) supplies electric power to the device under test 120. The automatic test equipment (ATE; 500) operates the device under test 120 and compares the predicted response and the output signal to determine whether the device under test 120 has a defect.

The automatic test equipment (ATE; 500) may include a controller for controlling various aspects of the test equipment such as the position of the optical device 200, the temperature of the device under test 120, a DC voltage supplied to a graphene structure, the selected lens, and the input signal applied to the device under test 120. The controller may be a general purpose computer, processor, dedicated hardware, or firmware (e.g., an electronic or optical circuit, such as application-specific hardware, such as, for example, a digital signal processor (DSP) or a field-programmable gate array (FPGA)). The controller may implement computer instructions or software for performing the actions described in the specification. As is understood, “software” refers to prescribed rules to operate a computer, such as code or script. The instruction or software may be stored in a computer readable storage medium, which may comprise conventional memory of a computer, such as a hard drive (which may be a solid state drive, DRAM, NAND flash memory, etc.).

In this way, the optical fault isolation apparatus 200 is connected to the automatic test equipment (ATE; 500) that operates the device under test 120 and detects the fault position inside the device under test 120 by radiating a light to the back side of the device under test 120 by the automatic test equipment (ATE; 500) while the device under test 120 is actually operating.

The optical fault isolation apparatus 200 may be operated in a state in which the test socket 100 is exposed to a room temperature environment. In addition, the optical fault isolation apparatus 200 is connected to the automatic test equipment (ATE; 500) in order to operate the device under test 120 and, because the optical fault isolation apparatus 200 device itself is large, it is also realistically difficult to place the optical fault isolation apparatus 200 in a temperature controlled chamber. The optical fault isolation apparatus 200 is very effective for an analysis of faults in a device under test at room temperature, but faults in a device under test typically do not occur only at a room temperature.

The quality of semiconductor products must be verified and/or guaranteed not only at room temperature but also at high temperatures. In particular, the quality of the semiconductor products for automobiles must be verified and/or guaranteed even at temperatures of 105° C. and greater. In order to meet these strict quality standards, automotive semiconductor products undergo burn-in tests and/or high temperature tests. Faults that occur in high-temperature environments are mainly temperature margin faults and even semiconductor products that have been determined to have faulted often operate normally again when the temperature is lowered. Therefore, testing of the semiconductor products in a high-temperature environment and finding the fault position within the semiconductor product in the high-temperate environment may be beneficial, and the quality of the semiconductor products may be improved, which may lead to improved yield of the semiconductor products.

According to the present disclosure, a test socket is provided that includes a graphene structure with excellent electrical conductivity, thermal conductivity, and optical transmittance. Using the disclosed test socket enables a fault analysis using an optical fault isolation (OFI) in a high temperature environment.

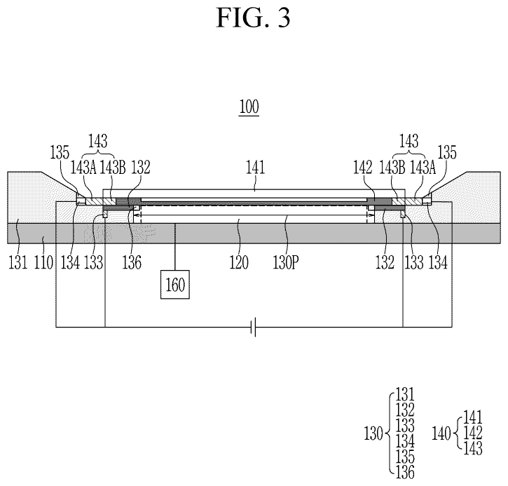

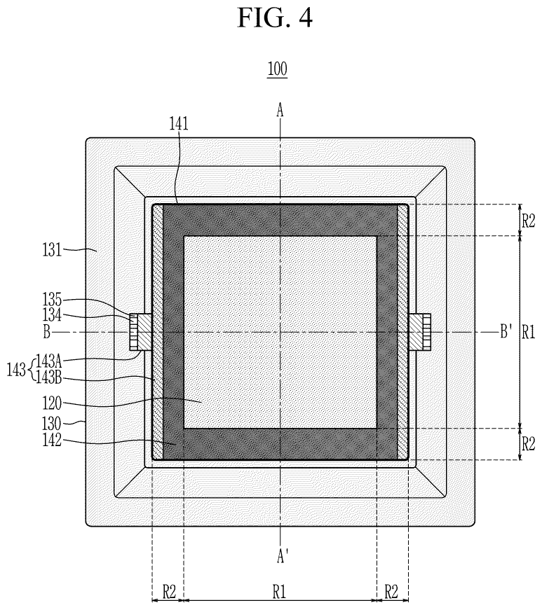

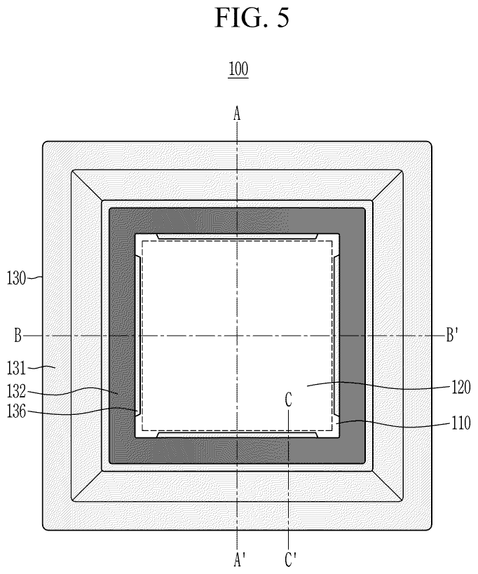

FIG. 2 is a view showing a cross-section of a test socket 100 of an embodiment. FIG. 2 is a cross-sectional view showing the test socket 100 of FIG. 4 and FIG. 5 taken along a line A-A′. FIG. 3 is a view showing another cross-section of a test socket 100 of the embodiment. FIG. 3 is a cross-sectional view showing the test socket 100 of FIG. 4 and FIG. 5 taken along a line B-B′.

Referring to FIG. 2 and FIG. 3, the test socket 100 includes a socket base 110, a socket cover 130, and a heating unit 140. The test socket 100 as shown in FIGS. 2 and FIG. 3 is inverted relative to the orientation shown in FIG. 1.

The socket base 110 is a part where the device under test 120 is mounted and fixed. The device under test 120 is shown with a dotted outline. The device under test 120 is mounted on the socket base 110 so that the front surface of the device under test 120 faces the socket base 110 and the rear surface of the device under test 120 faces the heating unit 140. The socket base 110 may support the front surface of the device under test 120. In an embodiment, the device under test 120 may be a semiconductor package, a semiconductor chip, or a semiconductor die. The socket base 110 includes contact pins. During testing, the contact pins of the socket base 110 are electrically connected to terminals formed on the traces on the front side of the device under test 120. For example, the contact pins may contact the terminals formed on the traces of the front side of the device under test 120. The socket base 110 includes wires inside that may be electrically connected to the traces on the front side of the device under test. The wires of the socket base 110 are connected to the probe card 300. The wires may transmit electrical signals through the socket base 110. The socket base 110 may transmit electrical signals generated by the automatic test equipment (ATE; 500) to the device under test 120. The electrical signals may be generated by the automatic test equipment (ATE; 500) and be transmitted through the interface module 400 and the probe card 300 before reaching the socket base 110. In an embodiment, the socket base 110 may include a temperature sensor 160 and/or may include wires connected to the external temperature sensor 160 of the socket base 110.

The socket cover 130 may be placed on and/or coupled to the socket base 110. The socket cover 130 includes a cover part 131, a first graphene structure 132, and a guiding part 136. The cover part 131 covers the socket base 110. The cover part 131 includes a through opening 130P passing through the cover part 131. During testing, the device under test 120 is positioned within the through opening 130P of the cover part 131. The through opening may be sized to receive the device under test 120. For example, the through opening may have shape that conforms to the device under test 120, but which may be slightly larger. The guiding part 136 extends from the cover part 131 or the first graphene structure 132 towards the device under test 120. The guiding part 136 may extend into the through opening 130P. The guiding part 136 secures the device under test 120 and may secure the device under test 120 in the through opening 130P. In another embodiment, the socket cover 130 may not include the guiding part 136, and the device under test 120 may contact the first graphene structure 132.

Referring to FIG. 3, the socket cover 130 includes a first electrode 133 inside the cover part 131. The first electrode 133 may be one of a plurality of first electrodes 133. The first electrode 133 is electrically and physically connected to the first graphene structure 132 and may contact the first graphene structure 132. The socket cover 130 may include pins 134 and an electrode receiver 135. The electrode receiver 135 may be one of a plurality of electrode receivers 135. The pins 134 are electrically and physically connected to a second electrode 143 within the electrode receiver 135 and may contact the second electrode 143. The second electrode 143 may be one of plurality of second electrodes 143. The electrode receiver 135 accommodates the second electrode 143, which is electrically and physically connected to a second graphene structure 142. A group of the first electrodes 133 may be connected in series by a wire to a DC power source and a group of the second electrodes 143 may be connected in series by another wire to the same or a different DC power source. The group of first electrodes and the group of second electrodes 143 may be connected in parallel to the DC power source by a wire. When a DC voltage is applied to the electrodes on one side of the first graphene structure 132, such as to one of the first electrodes 133, and to one side of the second graphene structure 142, such as to one of the second electrodes 143, and an opposite side of the first graphene structure 132 and an opposite side of the second graphene structure 142 is connected to a ground, such as another first electrode 133 on an opposite side of the first graphene structure 132 and/or the another second electrode 143 on an opposite side of the second graphene structure 142, an electrical circuit is formed and the first graphene structure 132 and the second graphene structure 142 generate heat which is transferred to the device under test 120. The DC voltage applied to the first graphene structure 132 and the second graphene structure 142 may each be individually controlled. For example, although FIG. 3 shows an electrical circuit in which a circuit formed by the first electrodes 133 and a circuit formed by the second electrodes 143 are in parallel, in other embodiments the first electrodes 133 and the second electrodes 143 may form independent circuits with separate DC voltages. The shape, the arrangement, the structure, and the number of the first electrodes 133, the pins 134, and the electrode receivers 135 are not limited to the above, and the first electrodes 133, the pins 134, and the electrode receivers 135 may have various shapes, arrangements, structures, and numbers.

The first graphene structure 132 is placed on and/or secured to the cover part 131. During testing, the first graphene structure 132 is placed in a position adjacent to the device under test 120. The first graphene structure 132 may be in contact with the device under test 120. The first graphene structure 132 functions to heat the device under test 120 and minimize heat applied to the device under test 120 from being leaked to the external environment. Therefore, during testing for fault detection, a high temperature applied to the device under test 120 may be maintained, and/or a high temperature environment for the device under test 120 may be maintained.

The heating unit 140 may be placed on and/or secured to the socket cover 130. The heating unit 140 covers the through opening 130P of the cover part 131 of the socket cover 130. The heating unit 140 covers the device under test 120. The heating unit 140 includes a transparent plate 141 and the second graphene structure 142.

The transparent plate 141 is placed on and/or secured to the second graphene structure 142. The test socket 100 may be selectively mounted on the optical fault isolation apparatus 200 so that the transparent plate 141 of the heating unit 140 faces the light source. Therefore, the laser light from the light source passes through the transparent plate 141 and irradiates the device under test 120. The laser light is reflected from the device under test 120 and passes through the transparent plate 141 and is transmitted to the optical device 220.

The second graphene structure 142 is placed under the transparent plate 141. The second graphene structure 142 covers the through opening 130P of the cover part 131 of the socket cover 130. The second graphene structure 142 covers the device under test 120. The second graphene structure 142 includes a first region R1 and a second region R2. The first region R1 and the second region R2 may correspond to non-overlapping portions of a major plane of the second graphene structure 142 (e.g., the largest plane of the second graphene structure 142) The first region R1 is positioned on the through opening 130P of the cover part 131. The second region R2 is positioned around the first region R1. The second graphene structure 142 in the first region R1 has a thickness thinner than the thickness of the second graphene structure 142 in the second region R2. The first region R1 of the second graphene structure 142 transmits the laser light so that the laser light reaches the device under test 120 (e.g., the second graphene structure 142 may be transparent to the laser light). The laser light from the light source passes through the second graphene structure 142 of the first region R1 and is incident on the device under test 120, and the laser reflected from the device under test 120 passes through the second graphene structure 142 of the first region R1 and is transmitted to the optical device 220.

The second region R2 of the second graphene structure 142 heats the device under test 120. Therefore, a high temperature fault detection test of the device under test 120 may be performed in a high temperature environment. Referring to FIG. 3, the second electrode 143 is electrically and physically connected to and/or contacts a first lateral side of the second graphene structure 142 and a second lateral side opposite to the first lateral side. The second electrode 143 is electrically and physically connected to and/or contacts the pins 134 in the electrode receiver 135. According to the present disclosure, the first graphene structure 132 and the second graphene structure 142 apply a high temperature only to the device under test 120 that is surrounded by the first graphene structure 132 and the second graphene structure 142, and the high temperature is not applied outside the test socket 100, thereby not affecting the equipment performance of the optical fault isolation apparatus 200.

FIG. 4 is a top plan view showing a test socket 100 of an embodiment including the heating unit 140. Compared to FIG. 5 in which the heating unit 140 is not shown, in FIG. 4, since the transparent plate 141 and the second graphene structure 142 of the heating unit 140 are positioned on the device under test 120, the device under test 120 of FIG. 4 is shown to be transparent through the transparent plate 141 and the second graphene structure 142.

Referring to FIG. 4, the transparent plate 141 of the heating unit 140 and the second graphene structure 142 are placed on the socket cover 130 and cover the device under test 120. The heating unit 140 includes a first region R1 and a second region R2. The second graphene structure 142 in the first region R1 is formed to have a thickness thinner than the thickness of the second graphene structure 142 in the second region R2 to have a high transmittance for a laser light. The heating unit 140 according to the present disclosure is configured to heat the device under test 120 in the first region R1 and simultaneously transmit the laser so that the laser may reach the device under test 120. The second region R2 is positioned around the first region R1. The second graphene structure 142 in the second region R2 is formed to have a thickness thicker than the thickness of the second graphene structure 142 in the first region R1 and is configured to heat the device under test 120. The second electrode 143 is disposed on a first lateral side of the second graphene structure 142 and a second lateral side opposite to the first lateral side.

The second electrode 143 includes a second electrode plug 143A and a second electrode main body 143B. The second electrode plug 143A is placed within the electrode receiver 135. The second electrode plug 143A is electrically and physically connected to the pins 134 in the electrode receiver 135. The second electrode plug 143A may have a shape that protrudes from the second electrode main body 143B. The second electrode plug 143A is electrically and physically connected to the second electrode main body 143B. The second electrode main body 143B may have a shape that extends conformally along the first lateral side of the second graphene structure 142 and the second lateral side opposite to the first side. The second electrode main body 143B is electrically and physically connected to and/or contacts the second graphene structure 142.

FIG. 5 is a top plan view showing a test socket 100 of an embodiment without a heating unit 140.

Referring to FIG. 5, the socket cover 130 may be selectively placed on the socket base 110. The socket cover 130 is positioned to surround the device under test 120 fixed on the socket base 110. The first graphene structure 132 of the socket cover 130 is positioned to surround the device under test 120. The arrangement of the first graphene structure 132 may be the same as that described previously. The socket cover 130 according to the present disclosure fixes and protects the device under test 120, heats the device under test 120 through a DC voltage applied to the first graphene structure 132, and prevents the heat applied to the device under test 120 from being lost to the external environment.

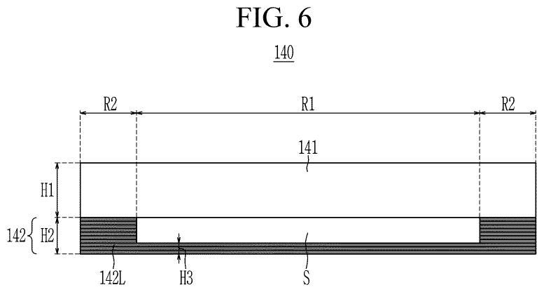

FIG. 6 is a cross-sectional view showing a heating unit 140 of an embodiment.

Referring to FIG. 6, the heating unit 140 includes a transparent plate 141 and a second graphene structure 142.

The transparent plate 141 is placed on the second graphene structure 142. In order to secure images of high quality and high magnification, the transparent plate 141 is preferably manufactured from a material with high transmittance in the near-infrared region. Additionally, for high temperature analysis, the transparent plate 141 is preferably made of a material with high heat resistance and low thermal expansion coefficient. In an embodiment, the transparent plate 141 may include quartz. Quartz has a transmittance of about 0.9 in a wavelength region of 1340 nm, which is the near-infrared region. Also, the quartz has a thermal expansion coefficient of about 0.55×10⁻⁶ m/m° C., a hardness value of 7, a tensile strength value of about 4.8×10⁷ Pa N/m2. Quartz has high transmittance, high heat resistance, and low thermal expansion coefficient in the near-infrared region. The characteristics of quartz, which has high transmittance, high heat resistance, and low thermal expansion coefficient in the near-infrared region, allow more second graphene structures 142 to be stacked compared to other materials. In another embodiment, the transparent plate 141 may include glass or polyethylene terephthalate (PET) material. In an embodiment, the transparent plate 141 may have a thickness H1 of about 10 μm to about 10 mm.

The second graphene structure 142 includes graphene layers 142L. Graphene is one of the allotropes of carbon and has a stable hexagon atom structure with carbon atoms in a honeycomb structure and a lattice-shaped secondary plane structure. As such, graphene has a stable chemical structure, and an electrical conductivity and/or a thermal conductivity thereof are superior to silicon and copper. The electron mobility of graphene is about 200 cm²/Vs. The thermal conductivity of graphene is about 3,000 to about 5,000 W/mK. As a material for the heating unit 140 that applies heat to the device under test 120, graphene is a superior material compared to silicon and copper. In an embodiment, the graphene layer may be formed by performing a chemical vapor deposition (CVD) or atomic layer deposition (ALD). In an embodiment, the graphene layer 142L may have a thickness in the vertical direction of about 0.1 nm to about 100 nm. The first thickness H3 of the second graphene structure 142 in the first region R1 is thinner than the second thickness H2 of the second graphene structure 142 in the second region R2. In an embodiment, the total number of the graphene layers 142L in the first region R1 may be 3 or less. In an embodiment, the total number of the graphene layers 142L in the second region R2 may be 10 or more. In some embodiments, the second graphene structure 142 may not have a discernable boundary between layers or may be formed as a single structure having “material continuity”. “Material continuity” may refer to structures and/or layers that are formed at the same time and of the same material, without a break in the continuity of the material of which they are formed. As one example, structures and/or layers that are in “material continuity” may be homogeneous monolithic structures. In the first region R1, the second graphene structure 142 is in contact with the device under test 120. In the first region R1, the second graphene structure 142 is not in contact with the transparent plate 141. A space S is formed between the second graphene structure 142 and the transparent plate 141 in the first region R1.

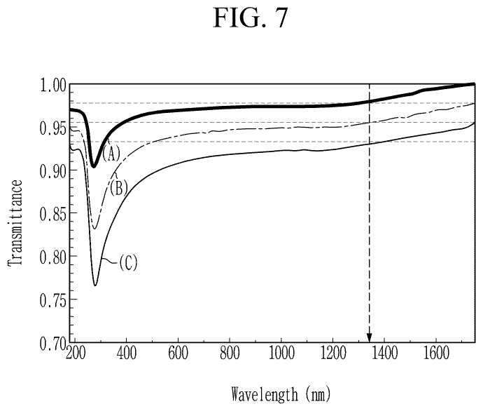

FIG. 7 is a graph showing a transmittance of a graphene layer 142L according to a wavelength of a light source.

Referring to FIG. 7, a transmittance of a graphene layer 142L according to a wavelength of a light source is shown (A) when the number of the graphene layer 142L is 1, (B) when the number of the graphene layer 142L is 2, and (C) when the number of the graphene layer 142L is 3. Referring to the graph, in 1064 nm to 1340 nm of the wavelength region, which is the wavelength region of the laser, which is the light source, excellent transmittance of about 92% to about 98% was shown in all three cases (A), (B), and (C). Particularly, even when the number of the graphene layer 142L (C) is three, which is the most disadvantageous in terms of the transmittance, it was found to have a transmittance of about 92% or more. Additionally, it was shown that the transmittance decreases by approximately 2.5% each time whenever the number of the graphene layers 142L was increased by one. If too many graphene layers 142L are stacked, a higher temperature may be obtained under the same voltage and current, but the transmittance decreases. According to the present disclosure, the image quality of high temperature fault analysis and the transmittance of the laser may be improved by stacking three or fewer graphene layers 142L on the first region R1 through which the laser transmits. In addition, by stacking more than 10 graphene layers 142L in the second region R2, where the laser does not penetrate, a high temperature environment for the fault analysis may be created and the thermal efficiency may be improved.

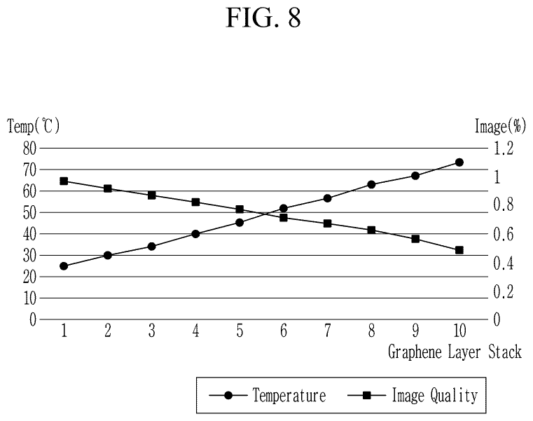

FIG. 8 is a graph showing an internal temperature and an analysis image quality of a socket according to the number of graphene layers 142L.

Referring to FIG. 8, whenever the number of stacked graphene layers 142L is increased by one, it is advantageous to increase the temperature of the device under test 120, but on the contrary, it may be seen that the image quality of the fault analysis decreases. Based on this graph analysis, the stacking limit of the graphene layer 142L may be determined, and according to the present disclosure, no more than three graphene layers 142L may be stacked in the first region R1 through which the laser penetrates.

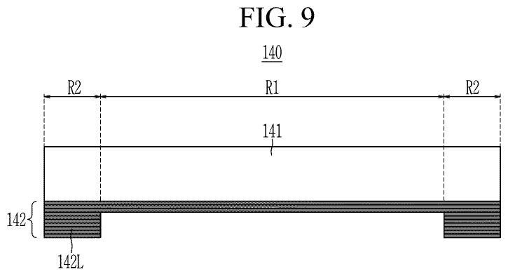

FIG. 9 is a cross-sectional view showing a heating unit 140 of an embodiment.

Referring to FIG. 9, a heating unit 140 includes a transparent plate 141 and a second graphene structure 142. In the first region R1, the second graphene structure 142 is in contact with the transparent plate 141. In the first region R1, the second graphene structure 142 is not in contact with the device under test 120. A space is formed between the second graphene structure 142 in the first region R1 and the device under test 120.

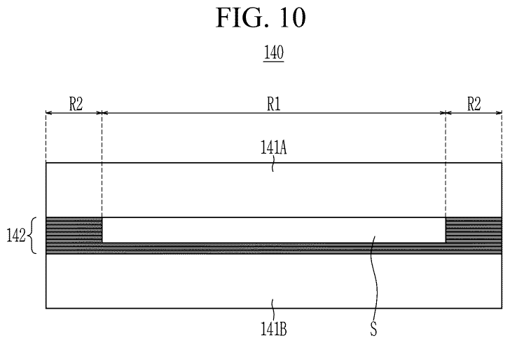

FIG. 10 is a cross-sectional view showing a heating unit 140 of an embodiment.

Referring to FIG. 10, a heating unit 140 includes a first transparent plate 141A, a second graphene structure 142, and a second transparent plate 141B. The second graphene structure 142 is interposed between the first transparent plate 141A and the second transparent plate 141B. In an embodiment, in the first region R1, the second graphene structure 142 may be in contact with the first transparent plate 141A. In an embodiment, in the first region R1, the second graphene structure 142 may be in contact with the second transparent plate 141B.

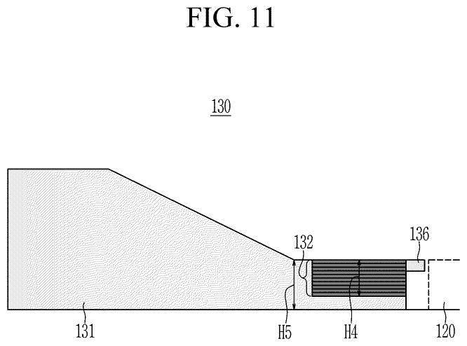

FIG. 11 is a cross-sectional view showing a socket cover 130 of an embodiment. FIG. 11 is a cross-sectional view showing the socket cover 130 of the test socket 100 in FIG. 5 taken along a line C-C′.

Referring to FIG. 11, a socket cover 130 incudes a first graphene structure 132. The first graphene structure 132 is placed on the cover part 131. The first graphene structure 132 includes graphene layers. The first graphene structure 132 is disposed at a position adjacent to the device under test 120. The first graphene structure 132 heats the device under test 120, continuously supplies heat to the device under test 120, and minimizes heat applied to the device under test 120 from being leaked to the external environment. The first graphene structure 132 has a thickness H4 in the vertical direction that covers at least a portion of each side among the sides of the device under test 120 in the vertical direction. In an embodiment, the first graphene structure 132 may have a thickness H4 in the vertical direction that is less than or equal to the thickness H5 of the cover part 131 in the vertical direction. In an embodiment, the number of the graphene layers in the first graphene structure 132 may be 10 or more.

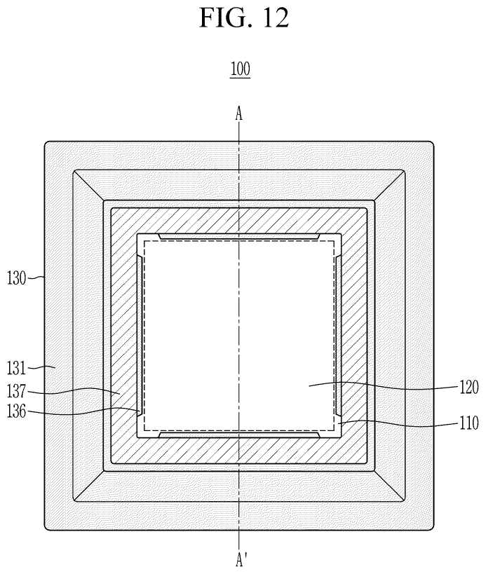

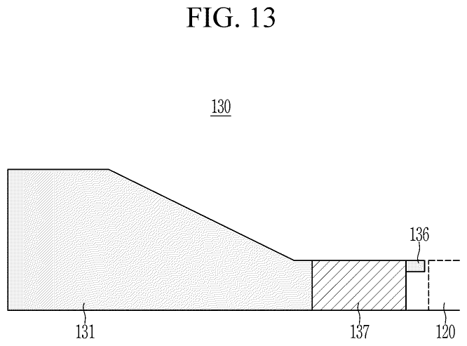

FIG. 12 is a top plan view showing a test socket 100 of an embodiment without a heating unit 140. FIG. 13 is a cross-sectional view showing a socket cover 130 of an embodiment. FIG. 13 is a cross-sectional view showing a socket cover 130 of the test socket 100 in FIG. 12 cut along a line C-C′.

Referring to FIG. 12 and FIG. 13, a socket cover 130 includes a heating part 137. The heating part 137 of the socket cover 130 is positioned to surround the device under test 120. The heating part 137 according to the present disclosure functions to heat the device under test 120 and to minimize heat applied to the device under test 120 from being leaked to the external environment. Therefore, during the testing for fault detection, a high temperature environment for the device under test 120 may be created and maintained. In one embodiment, the heating part 137 may include a copper wire, an aluminum wire, a tungsten wire, a nichrome wire, or various other heating bodies. In one embodiment, the heating part 137 may include a heating element of a resistance heating type. In an embodiment, the heating part 137 may include a heat plate or a conductive plate. The heating part 137 is coupled in series with the DC power source by a wire placed on the cover part 131 or the socket base 110. When a voltage is applied to the DC power source, the heating part 137 generates heat and applies heat to the device under test 120.

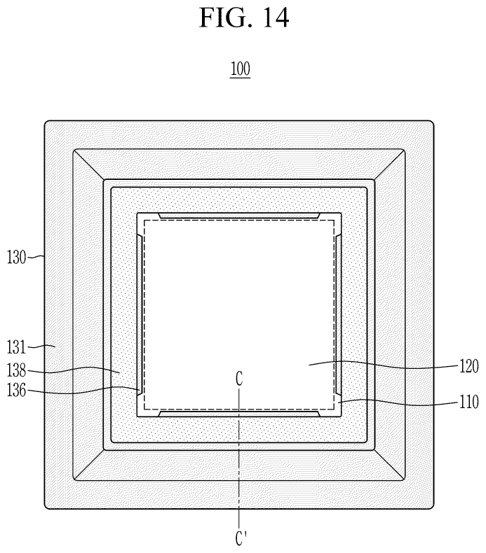

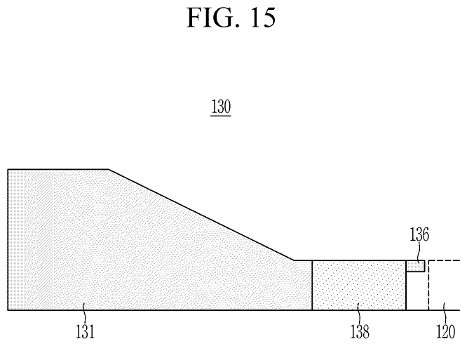

FIG. 14 is a top plan view showing a test socket 100 of an embodiment without a heating unit 140. FIG. 15 is a cross-sectional view showing a socket cover of an embodiment. FIG. 15 is a cross-sectional view showing the socket cover 130 of the test socket 100 in FIG. 14 cut along a line C-C′.

Referring to FIG. 14 and FIG. 15, a socket cover 130 includes an insulation part 138.

The insulation part 138 of the socket cover 130 is positioned to surround the device under test 120. According to the present disclosure, the insulation part 138 functions to minimize heat applied to the device under test 120 from the heating unit 140 from being leaked to the external environment. Therefore, during the testing for fault detection, a high temperature environment for the device under test 120 may be created and maintained. In an embodiment, the insulation part 138 may include a material having a thermal conductivity of less than about 0.8 W/(Km). In an embodiment, the insulation part 138 may include epoxy-based materials or resin-based materials.

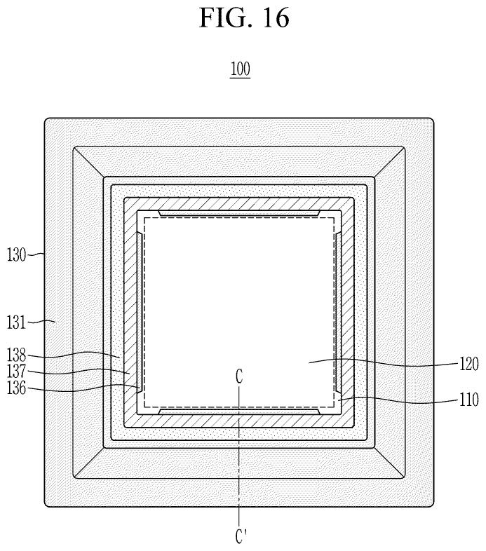

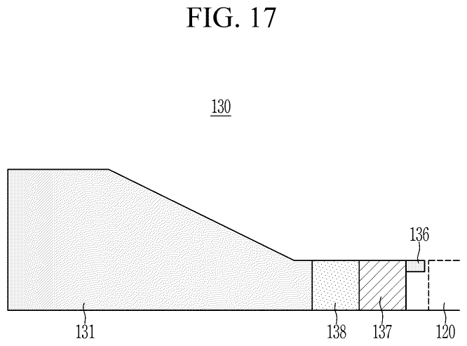

FIG. 16 is a top plan view showing a test socket 100 of an embodiment without a heating unit 140. FIG. 17 is a cross-sectional view showing a socket cover 130 of an embodiment. FIG. 17 is a cross-sectional view showing the socket cover 130 of the test socket 100 in FIG. 16 cut along a line C-C′.

Referring to FIG. 16 and FIG. 17, the socket cover 130 includes a heating part 137 and an insulation part 138. The heating part 137 is positioned to surround the device under test 120. The insulation part 138 surrounds the heating part 137. According to the present disclosure, the heating part 137 heats the device under test 120, and the insulation part 138 functions to minimize heat applied to the device under test 120 from being leaked to the external environment. Therefore, during the testing for fault detection, a high temperature environment for the device under test 120 may be created and maintained. For the heating part 137 and the insulation part 138, the contents of the heating part 137 and the insulation part 138 described in FIG. 12 to FIG. 15 may be applied.

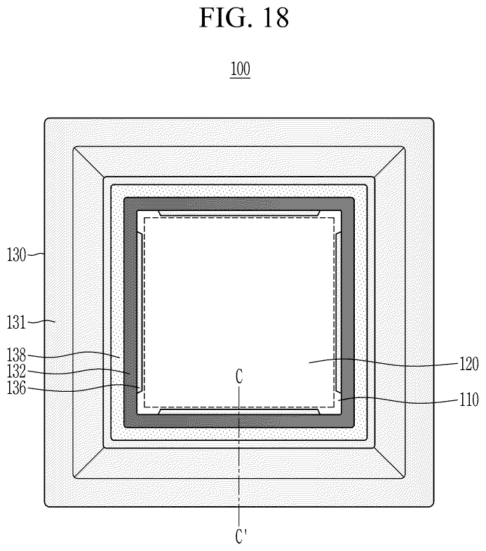

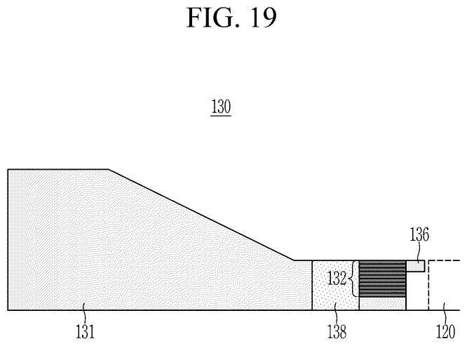

FIG. 18 is a top plan view showing a test socket 100 of an embodiment without a heating unit 140. FIG. 19 is a cross-sectional view showing a socket cover 130 of an embodiment. FIG. 19 is a cross-sectional view showing the socket cover 130 of the test socket 100 in FIG. 18 cut along a line C-C′.

Referring to FIG. 18 and FIG. 19, the socket cover 130 includes a first graphene structure 132 and an insulation part 138. The first graphene structure 132 is positioned to surround the device under test 120. The insulation part 138 surrounds the first graphene structure 132. According to the present disclosure, the first graphene structure 132 heats the device under test 120, and the insulation part 138 functions to minimize heat applied to the device under test 120 from being leaked to the external environment. Therefore, during the testing for fault detection, a high temperature environment for the device under test 120 may be created and maintained. For the first graphene structure 132 and the insulation part 138, the contents of the first graphene structure 132 and the insulation part 138 described in FIG. 2, FIG. 3, FIG. 5, FIG. 11, FIG. 14, and FIG. 15 may be applied.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A test socket comprising:
a socket base configured to support a device under test;
a socket cover on the socket base, wherein the socket cover includes a cover part covering the socket base and the cover part includes a through opening configured to house the device under test; and
a heating unit on the socket cover, wherein the heating unit includes
a graphene structure covering the through opening, and
a first transparent plate on the graphene structure,
wherein
the graphene structure includes a first region positioned on the through opening and a second region surrounding the first region,
the first region and the second region are non-overlapping portions of a major plane of the graphene structure,
the graphene structure has a first thickness in a vertical direction in the first region and a second thickness in the vertical direction in the second region, and
the first thickness is thinner than the second thickness.

2. The test socket of claim 1, wherein:
the graphene structure is positioned to be in contact with the device under test.

3. The test socket of claim 1, wherein:
the graphene structure includes a plurality of graphene layers, and
the plurality of graphene layers is stacked.

4. The test socket of claim 3, wherein:
in the first region, the total number of graphene layers in the plurality of graphene layers is 3 or less.

5. The test socket of claim 3, wherein:
in the second region, the total number of graphene layers in the plurality of graphene layers is 10 or more.

6. The test socket of claim 1, wherein:
the heating unit further includes a second transparent plate, and
the graphene structure is interposed between the first transparent plate and the second transparent plate.

7. The test socket of claim 6, wherein:
the first transparent plate and the second transparent plate include quartz.

8. The test socket of claim 1, wherein:
the socket cover further includes an insulation part around the through opening.

9. The test socket of claim 1, wherein:
the socket cover further includes a heating part around the through opening.

10.A test socket comprising:
a socket base configured to support a device under test;
a socket cover on the socket base, wherein the socket cover includes
a cover part that covers the socket base and includes a through opening sized and shaped to receive the device under test; and
a first graphene structure around the through opening; and
a heating unit on the socket cover,
wherein the heating unit includes a second graphene structure covering the through opening and a transparent plate on the second graphene structure,
wherein the second graphene structure includes a first region positioned on the through opening, and a second region surrounding the first region, and the first region and the second region are non-overlapping portions of a major plane of the graphene structure,
the graphene structure has a first thickness in a vertical direction in the first region and a second thickness in the vertical direction in the second region, and
the first thickness is thinner than the second thickness.

11. The test socket of claim 10, wherein:
the socket cover further includes an insulation part around the first graphene structure.

12. The test socket of claim 10, wherein:
the first graphene structure is positioned to be in contact with the device under test.

13. The test socket of claim 10, wherein:
the first graphene structure has a thickness in the vertical direction that covers at least a portion of a vertical portion of each side of the device under test.

14. The test socket of claim 10, wherein:
the first graphene structure is in contact with the heating unit.

15. The test socket of claim 10, wherein:
the socket base includes a temperature sensor.

16. The test socket of claim 10, wherein:
the first graphene structure and the second graphene structure are each connected to an electrode.

17. The test socket of claim 10, wherein:
the first graphene structure and the second graphene structure are each individually electrically controlled.

18. An optical fault isolation apparatus comprising:
a test socket, wherein the test socket includes
a socket base configured to support a device under test;
a socket cover on the socket base, wherein the socket cover includes a cover part covering the socket base, and the cover part includes a through opening sized and shaped to receive the device under test; and
a heating unit on the socket cover, wherein the heating unit includes a
graphene structure covering the through opening,
the graphene structure includes a first region positioned on the through opening, and a second region around the first region, and the first region and the second region are non-overlapping portions of a major plane of the graphene structure,
the graphene structure has a first thickness in a vertical direction in the first region and a second thickness in the vertical direction in the second region, and the first thickness is thinner than the second thickness,
an optical device including a laser light source; and
a housing that accommodates the optical device, wherein the housing has an opening on an upper surface of the housing, and the test socket is mounted in the opening.

19. The optical fault isolation apparatus of claim 18, wherein:
the test socket is mounted in the opening so that the heating unit faces the laser light source.

20. The optical fault isolation apparatus of claim 18, wherein:
the graphene structure transmits laser light from the laser light source.
